(19) United States
(12) Patent Application Publication
(10) Pub. No.: US 2013/0340978 A1
(43) Pub. Date: Dec. 26, 2013

(54) TWO-PHASE COOLING SYSTEM FOR ELECTRONIC COMPONENTS

(71) Applicant: ABB TECHNOLOGY AG, Zurich (CH)

(72) Inventors: Francesco AGOSTINI, Zofingen (CH); Matteo Fabbri, Adliswil (CH); Thomas Gradinger, Aarau Rohr (CH)

(21) Appl. No.: 13/923,053

(22) Filed: Jun. 20, 2013

(30) Foreign Application Priority Data
Jun. 20, 2012 (EP) 12172752.3

(51) Int. Cl. H05K 7/20

(52) U.S. Cl. CPC H05K 7/20309; H05K 7/20318
USPC 165/104.21

(57) ABSTRACT

A two-phase heat exchanger for cooling at least one electronic and/or electric component includes an evaporator and a condenser. The evaporator transfers heat from the electronic and/or electric component to a working fluid. The condenser includes a roll-bonded panel, which has a first channel which has a first connection port and a second connection port. The evaporator has a second channel and first connection openings and second connection openings. The first connection port of the first channel is connected to one first connection opening of the evaporator and the second connection port of the first channel is connected to one second connection opening of the evaporator and the working fluid is provided to convey heat by convection from the evaporator to the condenser by flowing from the second channel through the first connection opening or the second connection opening of the evaporator towards the first channel.

### RELATED APPLICATION(S)

This application claims priority under 35 U.S.C. §119 to European Patent Application No. 12172752.3 filed in Europe on Jun. 20, 2012, the entire content of which is hereby incorporated by reference in its entirety.

### FIELD

The disclosure relates to the cooling of electronic and electric components. For example, the disclosure relates to a two-phase heat exchanger including an evaporator and a condenser for cooling at least one electronic and/or electric component, a power module with an electronic and/or electric component and a two-phase heat exchanger and the use of a power module with such a heat exchanger for cooling an electric and/or electronic component in a vehicle.

### BACKGROUND INFORMATION

In the field of electric and electronic devices, efficient cooling systems can be used to take up heat and convey the heat resulting from ohmic losses and switching losses of the electric and/or electronic components in order to prevent excessive overheating and damage or even failure to these electric and/or electronic components. Although the electric and electronic devices, such as power converters, drives and other electric installations including so-called power electronic components are being designed to be more and more powerful in terms of electric power there is an ongoing trend for miniaturization of the electric installations. The result of these normally contravening demands can be an ever increasing amount of undesired waste heat needs to be extracted out of such installations and emitted to suitable thermal carriers such as air streams or water cycles that can be tied to powerful cooling devices. In other words, the more compact the installation, the larger the power density and thus the larger the heat flux of such electric installations.

Water-cooled systems can deal well with high power densities. Water-cooled systems can transport the heat by convection, as a heat transfer medium, i.e. the water, receives the heat and the heated water is transported from the heat source to a heat sink in order to emit the heat and to cool down the water. A drawback of water-cooled systems resides in that they can be costly, prone to leakage and can require at least one pumping device. Because pumps can have moving parts that can be subject to attrition, the pumps can have a finite span of life and require maintenance and service. A further drawback resides in down time of the whole installation in case of a sudden breakdown of the pump or during its maintenance, leading to undesired losses of income.

Air cooled systems can be a known alternative to water-cooled systems. Such air cooled systems can include heat sinks that include an array of fins extending from a base plate. Although air cooled systems can be pumpless, at least one fan can be used instead to convey the thermal load emerging from the electric and/or electronic components off the fins to a stream of air acting as the thermal carrier. Within the heat sink the heat is transferred by conduction. In the air, the thermal load is transferred by conduction proximate to the fin surface in a direction normal to the surface and by convection. A drawback of common air cooling systems resides in that a large fin surface is used if the heat transfer coefficient between fin surface and air is low. If the available space is scarce, then the fins can be distanced to one another often by inter-fin channels having a small width only. In addition, the higher the velocity of the air stream, the higher the pressure drop and the higher the level of acoustic noise caused by the fan needed to convey the air. A common measure for avoiding these drawbacks resides in dedicating a comparatively large cross-section to the air stream/airflow, for example, in a channel or duct portion. As a result of that measure, known air cooling systems and thus whole electric installations can become rather bulky because the heat sinks have usually long, thick and consequently heavy cooling fins sticking into the air stream for ensuring an acceptable fin efficiency, i.e. acceptable heat conveyance. If the inter-fin channel width is small, then these inter-fin channels can be prone to clogging in dirty air environment such as heavy industry or railway. Moreover the bulkiness of the overall electric installation contravenes the ongoing trend to miniaturized equipment.

Hybrid cooling systems by two-phase heat exchangers are known to make use of both the advantages of water-cooled systems and air-cooled cooling systems. In addition, the heat transfer coefficient of such two-phase heat exchangers can be comparatively high and they may not require pumps or fans. Exemplary embodiments of such a two phase cooler with fin-like cooling panels are addressed in WO 2011/035943 A2, disclosing a passive loop-type thermosiphon cooling system. In WO 2011/035943 A2, two different concepts of a cooling system with a condenser made of roll-bonded panels are disclosed. In a first concept, an evaporator and condenser can be spatially separated and connected only through pipes and/or a manifold (see the embodiments shown in FIGS. 1-9 of WO 2011/035943 A2 for exemplary reference). In the second concept, the evaporator and the condenser can be spatially integrated to a system that essentially looks like a classical, finned heat sink. For example, it has a base plate, onto which the power electronic devices to be cooled can be mounted, and fins, which extend from the base plate, in a direction normal to the base plate. The second concept (see the embodiments shown in FIGS. 11-14 of WO 2011/035943 A2 for exemplary reference) can be advantageous in so far as it allows replacing power modules with cooling systems having classical finned heat sinks by a two-phase thermosiphon with similar appearance and overall dimensions. Compared to a known finned heat sink, the thermal efficiency of a cooling system according to the second concept can be much higher, because the heat in the fins is not only transported by conduction but also by convection of the two-phase working fluid flowing in the channels of the roll-bonded panels, which constitute the fins. The thermal fin efficiency is high enough that the second concept allows the cooled power-electronic devices to be operated with higher power and higher losses comparable to common cooling systems relying on known above-mentioned heat sinks. At the same time overheating of the electric and/or electronic devices to be cooled can be preventable in a reliable manner by the second concept. Alternatively, the higher cooling efficiency can increase the lifetime and the reliability of the power-electronic devices if the power and the losses of the power-electronic devices can be kept constant.

Although the second concept is thermally efficient and utilizes structurally less complex designs and assembly than the first concept, the second concept can be difficult to manufacture in an economic way. According to the second concept, a lower part of each panel including a section of the channel is inserted in a dedicated slot of the base plate. The whole base plate has several slots to receive the panels conferring a comb-like appearance to the base part when seen in a cross-section. For ensuring a good thermal performance, the thermal resistance between the slot walls and the panel surface of the roll-bonded panels are small. Expressed differently, an intimate contact between roll-bonded panels and the slot walls of the base is desirable. Even with known mass production technology, both the manufacture of the slots and a satisfactory thermal contact between the slots and the roll-bonded panels can impact economy.

### SUMMARY

A two-phase heat exchanger is disclosed for cooling at least one of an electronic and an electric component, the heat exchanger comprising: a condenser body including a plurality of roll-bonded panels having a first channel arranged between a first and a second sheet such that a first connection port delimits the first channel at one end and a second connection port delimits the first channel at another end, wherein the first sheet is connected to the second sheet by roll-bonding to form the roll-bonded panel; and an evaporator body including a second channel, wherein the second channel is delimited at one end by a third connection opening for each roll-bonded panel and at another end by a fourth connection opening for each roll-bonded panel, wherein the evaporator body includes a thermal connection surface to which at least one of an electronic and an electric component is thermally connectable, wherein the first connection port is connected to the third connection opening and wherein the second connection port is connected to the fourth connection opening such that the first channels and the second channel form a loop for guiding a working fluid that receives a thermal load producible by the at least one of an electronic and an electric component in an operating state of the heat exchanger at the evaporator body from the evaporator body to the condenser body for transferring the thermal load, wherein the third connection openings can be arranged in a first end region of the evaporator body and wherein the fourth connection openings can be arranged in a second end region of the evaporator body, and wherein the second end region is provided on an opposite end of the evaporator body with respect to the first end region.

### BRIEF DESCRIPTION OF THE DRAWINGS

These and other aspects of the present disclosure will become apparent from and elucidated with reference to the exemplary embodiments described herein.

FIG. 1 shows a simplified front view of a power module including a two-phase heat exchanger according to an exemplary embodiment of the disclosure;

FIG. 2 shows a perspective view of the power module according to an exemplary embodiment of the disclosure from the top left angle;

FIG. 3 shows a perspective view of the exemplary power module from the top right angle with a section through the heat exchanger along A-A of FIG. 1 and FIG. 2;

FIG. 4 shows a perspective view of an exemplary evaporator of the heat exchanger shown in FIG. 2;

FIG. 5 shows a perspective view of an exemplary base part of the evaporator shown in FIG. 4;

FIG. 6 shows a cross sectional view through the base part shown in FIG. 5 along section B-B;

FIG. 7 shows a cross sectional view through an alternative exemplary base part;

FIG. 8 shows a side view of an exemplary embodiment of a heat exchanger of the disclosure;

FIG. 9 shows a perspective view of an exemplary embodiment of a power module with a two-phase heat exchanger;

FIG. 10 shows a perspective view of the power module according to FIG. 9 including a sectional view through an exemplary condenser body and exemplary evaporator body along section C-C in FIG. 9;

FIG. 11 shows a perspective view of the power module according to FIG. 9 including a sectional view through the exemplary evaporator body along section D-D in FIG. 9;

FIG. 12 shows a close-up of an exploded view of the power module according to FIG. 9 in a similar perspective as in FIG. 9 including a sectional view through the evaporator body and the condenser body along section E-E in FIG. 9;

FIG. 13 shows a perspective view of the evaporator body of the power module embodiment shown in FIG. 9;

FIG. 14 shows a simplified side view of an exemplary embodiment of a roll-bonded condenser panel according to the disclosure; and

FIG. 15 shows exemplary orientations of the two-phase heat exchanger according to exemplary embodiments of the disclosure with respect to the direction of the gravitational force of the earth (G) in an operating state of the power module.

### DETAILED DESCRIPTION

Exemplary embodiments of the present disclosure can simplify the mechanical connection in between the roll-bonded panels and the base plate of a two-phase thermosiphon such that a more economic manufacturing process is achievable.

An exemplary embodiment of the two-phase heat exchanger according to the disclosure for cooling at least one of an electronic and/or an electric component according to the disclosure includes a condenser body that is thermally connected to an evaporator body. The condenser body includes a roll-bonded panel where a first channel for a phase-changing working fluid is arranged in between a first and a second sheet such that a first connection port delimits the first channel at one end and that a second connection port delimits the first channel at another end. The first sheet is connected to the second sheet by roll-bonding such that a roll-bonded panel is formed. The evaporator body includes a second channel, wherein the second channel is delimited at one end by a third connection opening and at another end by a fourth connection opening. The evaporator body includes a connection surface to which at least one of an electronic and an electric component is thermally connectable.

Further, the first connection port is connected to the third connection opening and wherein the second connection port is connected to the fourth connection opening such that the first channel and the second channel form a closed loop for guiding a working fluid that receives a thermal load producible by the at least one of an electronic and an electric component in an operating state of the heat exchanger at the evaporator body and from the evaporator body to the condenser body for dissipating the thermal load. Moreover, the third connection opening is arranged in a first end region of the evaporator body wherein the fourth connection opening is arranged in a second end region of the evaporator body. The second end region is provided on an opposite end of the evaporator body with respect to the first end region, for example, on opposite sides if the evaporator body has a cuboid overall shape such that a compact heat exchanger is achievable. The term “connection port” shall not be understood in a limited way for denoting merely an orifice, a hole or an opening but also as a three-dimensional element, for example a pipe or hose, which element forms a portion of the loop-type channel in between the first channel and the second channel that forms a fluid connection, for example, a fluid duct, for the working fluid.

The simplification of the mechanical connection between the roll-bonded panels and the base plate, such as an evaporator comparable to known devices can be achieved in that the evaporator body is designed to act as the actual evaporator for the working fluid and is thus a bodily different element than the condenser body. This can be achieved by the second channel that forms itself a portion (e.g., an essential portion) of the loop for the working fluid. As a result, the roll-bonded panel does not contain an evaporator portion any longer such that there is no need to embed the roll-bonded panel into the base plate/evaporator body. As a consequence, the base plate/evaporator body does not need to include any slots for receiving the roll-bonded panels any more. By doing so, the degree of design freedom for connecting the evaporator body to the roll-bonded panels, the evaporator body geometry as well as the evaporator panel can be increased to a maximum extent. Thus it becomes possible to connect an evaporator that is not manufactured by roll-bonding technology to roll-bonded panels forming the condenser. Moreover, a thermal interface of the conveyed heat from the base plate/evaporator to the roll-bonded panels as present in the thermosiphons according to the second known concept is avoided. Thermal interfaces can be undesired since they decrease the efficiency heat transport of a heat exchanger and thus affect the overall thermal efficiency.

The degree of design freedom for connecting the evaporator body to the roll-bonded panels can be further increased in that the third connection openings and the fourth connection openings can be allocated in different, opposite end regions of the evaporator body. Owing to that spatial separation of the third connection openings and the fourth connection openings, the accessibility to the connection ports and their dedicated connection openings is heavily improved and contributes thus to an economic manufacturing process. In an exemplary embodiment of the disclosure, a distance between the first end region and the second end region can be at least 0.5 times as long as the second channel of the evaporator body.

Moreover, a given length of the evaporator body can be used thermally optimally over almost its whole length if the at least one of an electric and an electronic component forming the heat source is allowed to extend over a substantial portion of that given length.

Depending on the embodiment of the evaporator body that forms the base plate, the thermal connection can be established in that the at least one of an electronic and an electric component can be pressed directly to the connection surface or indirectly, for example, in that an intermediate layer of a good thermal conductor such as copper or the like and/or a thermal grease is provided between the at least one of an electronic and an electric component and the connection surface. Where allowable, the at least one of an electronic and an electric component can be pressed towards the evaporator body by fastening these components directly to the evaporator body.

The number of roll-bonded panels of the condenser body depends on the heat output that shall be conferred to the thermal carrier like ambient air, for example. Hence embodiments of heat exchangers can be achievable where several condenser bodies can be fluidly connected to the evaporator body by several sets of a third connection opening and a fourth connection opening each.

The heat exchanger is charged with a working fluid that is allowed to circulate in the first channels and second channels in order to convey heat by convection from the evaporator body to the condenser panels by flowing from the second channel through the first connection opening or the second connection opening of the evaporator towards the first channel. Any working fluid, also referred to as refrigerant or coolant, for example, can be used. Depending on the conditions and requirements some suitable examples of a working fluid can be R134a, R245fa, R365mfc, R600a, carbon dioxide, methanol and ammonia.

The roll-bonded panels can be connected to the evaporator with a plug connection. Preferably, the actual connection of the roll-bonded panels to the evaporator can be performed by brazing or welding such that the roll-bonded panels can be not removable from the evaporator after assembly. Such a connection can improve the structural integrity of the two-phase heat exchanger. Brazed or welded thermosiphon heat exchangers can be further known to form lasting leak-proof connections of cooling systems. Provided that the inter-fin channel width or spacing, i.e. the distance in between two neighboring roll-bonded panels is large enough, clogging can be avoided easily.

In an economic way of manufacturing the thermosiphon heat exchanger, the condenser body and the evaporator body can be connected to one another at one time by CAB brazing (for example, NOCOLOK®) or vacuum brazing.

The two-phase heat exchanger, as described above and hereinafter, can work on the principle of thermosiphon systems. Thus, a pump is not needed to drive the circulation of the working fluid. When being vaporized in the evaporator, the working fluid vaporizes and rises from the evaporator to the roll-bonded panels, where the vaporized working fluid is condensated again. The condensated working fluid flows towards the evaporator, thus constituting a closed loop cooling circuit.

According to the thermosiphon principle, the flowing of the working fluid through the cooling circuit is held up by gravity and the different density of the vaporized and condensed working fluid.

The electronic and/or electric component can be every component that produces heat during its operation and needs to be cooled down, for example, a power electonioc component. The term power electronic components is used, for example, for diodes, thyristors and other semiconductor elements whose block-voltage is more than 400 Volts such that can be used in a power module, for example, for a drive or converter of a mill, a vehicle and the like.

The evaporator can be adapted to be connected to a multitude of roll-bonded panels. Thus, the working fluid rises in one of the multitude of roll-bonded panels through the first connection port or the second connection port when being vaporized in the evaporator and condensates when flowing through the first channel of the roll-bonded panel. After condensating back to its liquid state, the working fluid flows from the roll-bonded panel through the second connection port or the first connection port back to the second channel of the evaporator where the cycle starts anew.

According to an embodiment of the disclosure, the first connection port and the second connection port of the first channel can be located on a single edge of the roll-bonded panel.

Particularly good access to the connection openings and the connection ports can be achievable if the third connection opening or openings and the fourth connection opening or openings can be arranged on a common surface of the evaporator body. Owing to such a set-up, the connection of the roll-bonded panels to the evaporator can be simplified.

In a basic design of the evaporator body, the common surface where the roll-bonded panels can be attachable to, is arranged on an opposite end/side of the connection surface on the evaporator body where the at least one electronic and/or electric component is thermally connectable.

Depending on the embodiment of the roll-bonded panel, the connection ports can include a tubular end section, for example, a tube section that is brazed to the roll-bonded sheets. If the connection ports can be attached to the roll-bonded sheets, the bending stiffness of the connection ports decreases with increasing length of the connection ports. This effect can be targeted on purpose for compensating dimensional mismatches between the end portion of the first connection port facing the third connection opening and the dedicated third connection opening if the end portion of the second connection port facing the dedicated fourth connection opening matches its dedicated fourth connection opening. Reasons for dimensional mismatches can reside in manufacturing tolerances in terms of dimension and shape of both the evaporator body and the roll-bonded panels, different thermal expansion of the evaporator body and the roll-bonded panels or a combination thereof.

In a basic exemplary embodiment according to the disclosure for compensating such mismatches, the first connection port is longer than the second connection port when seen in a flow direction of the working fluid in an operating state of the heat exchanger. The first connection port is flexible such that it allows for compensating dimensional mismatches between the second connection port and the third connection opening.

Where suitable and/or desired, the second channel can be split into at least two sub-channels between the third connection openings and the fourth connection openings, for example, if the overall wetted surface of the evaporator body has to be maximized.

The first channel or channels shall be shaped and dimensioned according to the particular needs and requirements of the thermosiphon heat exchanger. The first channel might be split up into a set of sub-channels at the first connection port and bundled again at the second connection port in order to distribute the vaporized working fluid to a large surface of the condenser panel for condensation. Alternatively or in addition, the first channel can be provided in the roll-bonded panel to have a serpentine-like appearance. In any case it can be advantageous to adjust the inclination of the first channel and its subsections such that a motion (flow) of the working fluid can be promoted by gravity such that no pumps can be required. Similar measures can be taken if the working fluid shall have a predefined flow direction.

In an exemplary embodiment of the evaporator body according to the disclosure, the latter can include a base part with the second channel and a cover plate for vertically closing the second channel.

If the heat flow from the evaporator body into the working fluid exceeds a predefined threshold, a vapor promoting structure can be provided in the second channel for improving the vaporization rate. The vapor promoting structure can be any shape of the interior surface of the evaporator which supports a high heat transfer from the base part (where the heat sources can be connected to, i.e. the electronic and/or electric components) to the working fluid. Thus, the base part can itself have a vapor promoting structure with an increased surface. The purpose of the vapor promoting structure resides in increasing the wetted surface by creating sub-channels and decreasing the local heat flux in order to avoid the critical heat flux. Critical heat flux describes the thermal limit of a phenomenon where a phase change occurs during vaporization (such as bubbles forming on a metal surface used to heat the working fluid), which suddenly decreases the efficiency of heat transfer, thus causing local overheating of the heating surface.

According to an exemplary embodiment of the evaporator body according to the disclosure, the vapor promoting structure can have a honey-comb-like cross section when seen in the direction of the flow in the second channel such that a plurality of parallel extending sub-channels is formed. The comb-like cross section of the base plate includes peaks and valleys or ridges and recesses, wherein each recess can be adapted in order to form a second channel or sub-channel when covering the base part with the cover plate. Depending on the embodiment, the recesses forming the second channel or second channels can be provided in the base part only, in the cover plate only or partially in both the cover plate and the base plate.

The recesses of the base part having the comb-like cross section can also be interconnected such that the working fluid is collected in a manifold, wherefrom the vaporized working fluid flows towards the roll-bonded panels in an operating state of the thermosiphon.

According to an exemplary embodiment of the evaporator body according to the disclosure, the evaporator body includes a first manifold and/or a second manifold, wherein the first manifold is adapted to supply a plurality of second channels, For example, second channels that run in parallel to one another, with condensed working fluid in its liquid state flowing out of the second connection port of the first channel and wherein the second manifold is adapted to supply working fluid from the second channels to the first connection port of the first channel. Good vaporization results can be achievable due to an increased contact surface of the evaporator body to the working fluid if a majority of a length of the second channel or a sub-channel thereof is formed by a multi-port-extrusion (MPE) tube. Alternatively or in addition thereto the second channel might be split into at least two sub-channels between the first connection port and the second connection port for increasing the wetted overall surface of the evaporator body. Accordingly, the second manifold receives the vaporized working fluid from the second channels of the evaporator and supplies the vaporized working fluid to the roll-bonded panels for condensation.

According to an exemplary embodiment of the disclosure, a power module includes at least one two-phase heat exchanger as described above where at least one electronic and/or electric component is thermally connected to the connection surface of the evaporator body of the two-phase heat exchanger. Exemplary advantages mentioned in the context of the two-phase heat exchangers apply likewise to those of a power module having such a heat exchanger. The exemplary advantages mentioned earlier allow the power module described above for being used in a vehicle. The vehicle can be a bus, a train, a ship or an aircraft, for example. For example, the electric component can be a power supply unit such as a traction power converter or an auxiliary converter used in a train.

In the following description of exemplary embodiments of the disclosure, identical or at least functionally identical parts or elements can be provided with the same reference numerals in the figures. The exemplary embodiments shown in the figures can be schematical and not drawn to scale.

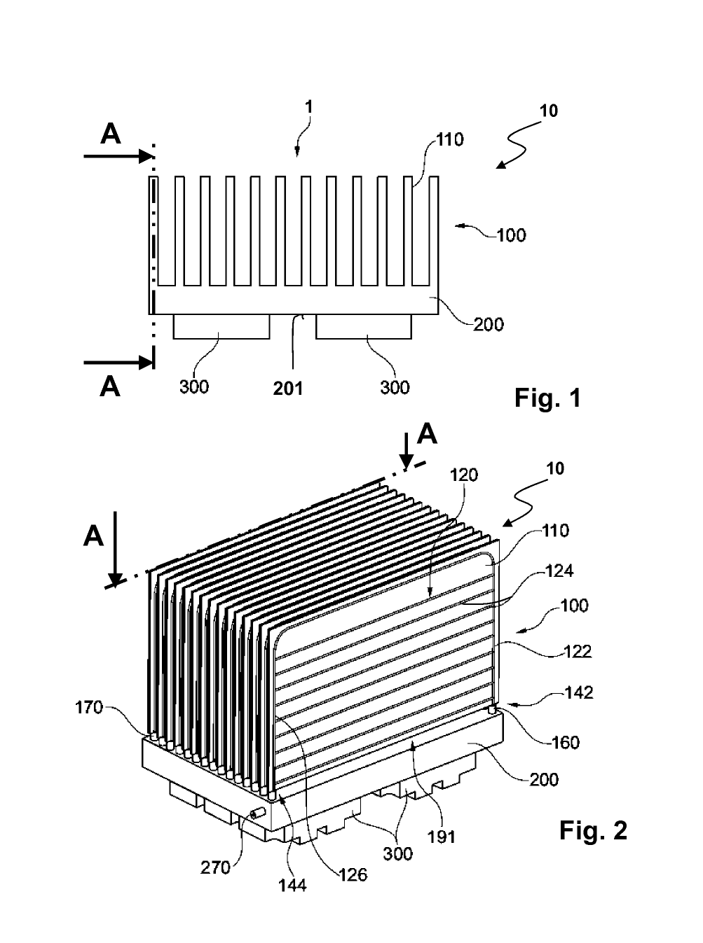

FIG. 1 shows a simplified schematic view of a power module including a two-phase heat exchanger 1 according to an exemplary embodiment of the disclosure. The heat exchanger 1 is employed for cooling at least one of an electronic and an electric component 300 including an evaporator body 200 and a condenser body 100. The condenser body comprises a plurality of roll-bonded panels 110. These roll-bonded panels 110 can be produced from aluminum sheet metal and can be thermally and mechanically permanently connected to the evaporator body 200 such that the heat exchanger 1 has a comb-like overall appearance like a known finned heat sink when see in cross-section. The roll-bonded panels 110 of the condenser 100 and the evaporator 200 can be connected or joined by CAB (controlled atmosphere brazing) or flame-brazing. Alternatively, the joining of the roll-bonded panels and the evaporator can be performed with any other feasible and appropriate method such as adhesives, for example, epoxy resin.

One or more electric or electronic components 300 can be attachable/attached to and their contact surface thermally connectable/connected to the evaporator 200, for example, by way of fastening, on a connection surface 201 in order to establish a thermally suitable heat transfer of the components 300 to a working fluid like R134a, for example, contained in the evaporator body 200.

FIG. 2 shows a perspective view of the power module according to an exemplary embodiment of the disclosure from the top left angle.

The roll-bonded panels 110 of the condenser body 100 can be connected to the evaporator body 200 via connection ports 142, 144, which connection ports include an inlet and/or outlet tube 160, 170 that allow the working fluid to move from the evaporator body 200 to the condenser body 100 and vice versa. The evaporator body 200 includes a filler plug 270 for charging the evaporator body 200 with the working fluid after manufacturing of the two-phase heat exchanger. The roll-bonded panels 110 have a first channel 120 for receiving the vaporized working fluid coming from the evaporator body each, such that the working fluid condenses when flowing through the first channel 120 of the roll-bonded panel 110 in an operating state of the power module. In the exemplary set-up of the roll-bonded panels 100 shown in FIG. 1, the first channel 120 departs from the first connection port 142 and includes a first portion 122 from where a plurality of third portions 124 running parallel to one another branches off. All these third portions 124 can be fluidly connected to a single second portion 126 which in turn is fluidly connected to the second connection port 144.

Both the first connection port 142 and the second connection port 144 can be located at a common first edge 191 proximate to a lateral edge of the roll-bonded panel 110, wherein the condenser panels 110 can be provided on an opposite end to the connection surface 201 of the evaporator body.

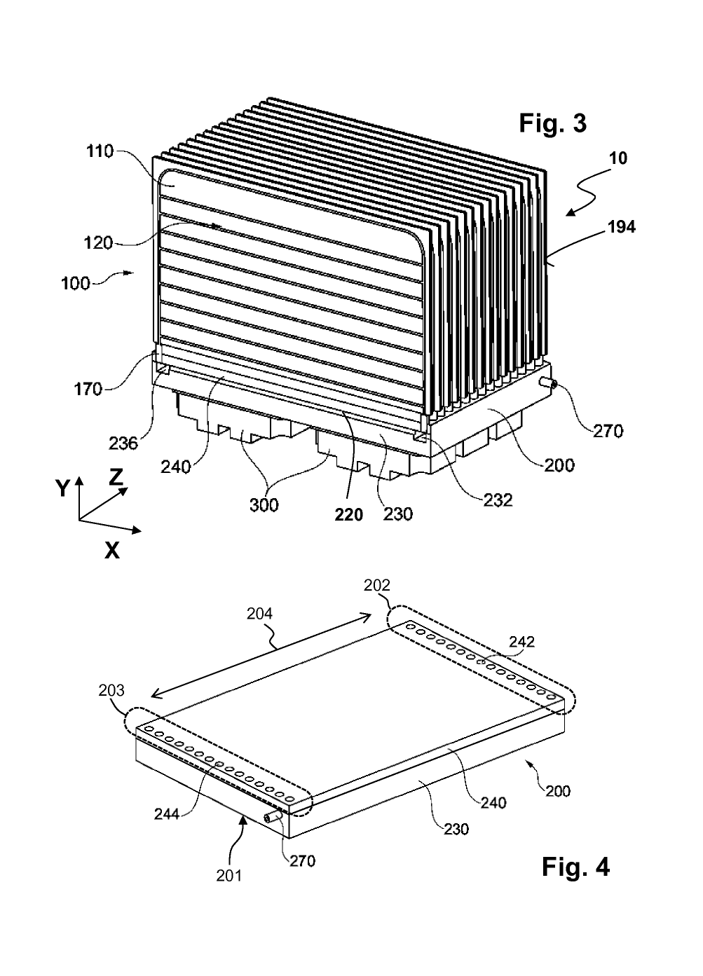

FIG. 3 shows a perspective view of the power module from the top right angle with a section through the heat exchanger along A-A of FIG. 1 and FIG. 2. Compared bed to FIG. 2, the heat exchanger is rotated about a vertical axis (Y) defined by the first portion 122 of the first channel 120, for example. Please note that the sectional surface along A-A is not shown in hatched style by exception as the hatched display might hamper the understandability and clarity of the cross-section.

The evaporator body 200 includes a base part 230 including a second channel 220 and a cover plate 240 for vertically delimiting a set of longitudinal portions of the second channel 220 that run parallel to one another in the same direction as the roll-bonded panels 110 (direction X). Both the base part 230 and the cover plate 240 can be made of aluminum or an alloy thereof that is suitable for being brazed together and to the roll-bonded condenser body 100. The vaporization of the working fluid takes place within these longitudinal portions of the second channel 220 in an operating state of the heat exchanger. The evaporator body 200 includes further two recesses 232, 236, one arranged at each end face of the evaporator body 200, which recesses extend transversely (direction Z) to the longitudinal direction of the longitudinal portions of the second channel 220. The longitudinal portions of the second channel 220 discharge at their ends into these recesses such that these recesses form a first manifold 232 and a second manifold 236, respectively. For further reference to the set-up of the base part 230 revert to FIGS. 5 and 6 and the description relating thereto.

The roll-bonded panels 110 can be connected to the evaporator 200 via the inlet tubes 160 and outlet tubes 170 forming the first connection port 142 and the second connection port 144 respectively such that the vaporized working fluid is allowed to rise in its vapor state from the first manifold 232 to the first channel 120 of the roll-bonded panels 110 and the condensed working fluid is allowed to flow back to the second manifold 236 in its liquid state again for a new working cycle again in an operating state of the heat exchanger.

The first channel 120 and the second channel 220 form a loop for guiding the working fluid within the heat exchanger 1. The movement of the working fluid in the operating state of the heat exchanger of this embodiment is driven by gravitation.

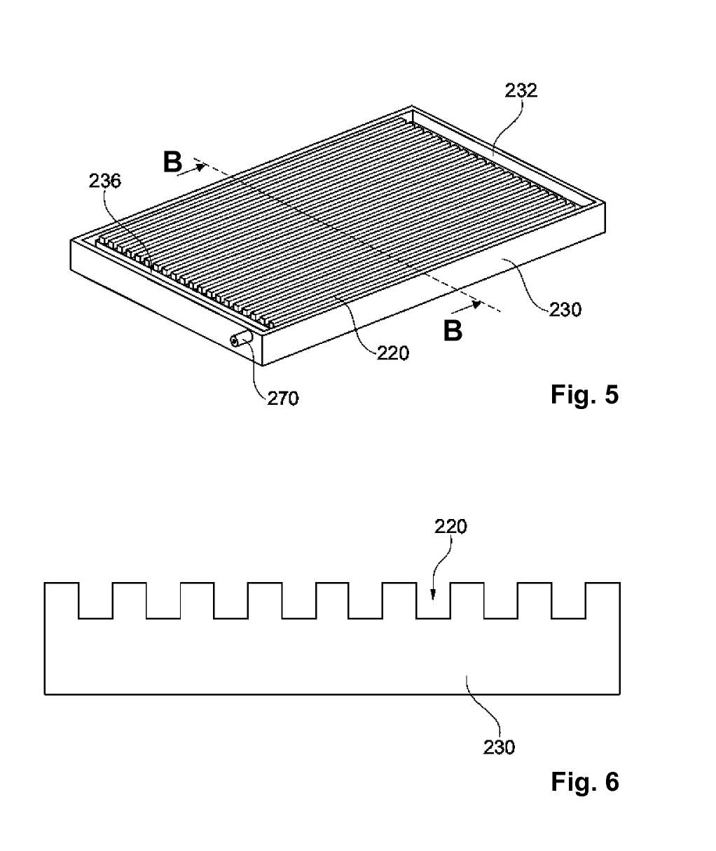

FIG. 4 shows a perspective view of an evaporator of the heat exchanger shown in FIG. 2. The evaporator 200 includes a base part 230 and a cover plate 240, wherein the cover plate 240 includes a set of third connection openings 242 and a set of fourth connection openings 244 each. The set of third connection openings 242 is arranged in a linear manner in a first end region 202 of the evaporator body 200. The set of fourth connection openings 244 is provided the same way at a second end region 203 located at an opposite end of the evaporator body 200 with respect to the first end region 202. The second end region 203 is separated from the first end region 202 by a distance 204. The third connection openings 242 can be provided for receiving the first connection ports 142 during assembly of the heat exchanger whereas the fourth connection openings 244 can be provided for receiving the second connection ports 144. Thus, the connection openings 242, 244 can be adapted to be connected via connection ports 142, 144 and/or connection tubes 160, 170 to the roll-bonded panels of the condenser body 200 accordingly.

FIG. 5 shows a perspective view of a base part of the evaporator shown in FIG. 4. As already mentioned in the context of FIG. 3 and with reference to FIG. 6, FIG. 5 displays that the plurality of longitudinal portions of the second channel 220 discharges at their ends into the first manifold 232 and the second manifold 236, respectively. The number of longitudinal portions of the second channel results of a compromise between a maximum number of second channels for improving the heat transfer from the base part to the working fluid and the increase in detrimental pressure drop and a blockage of the natural circulation of the working fluid where only as few channel portions as possible can be desirable.

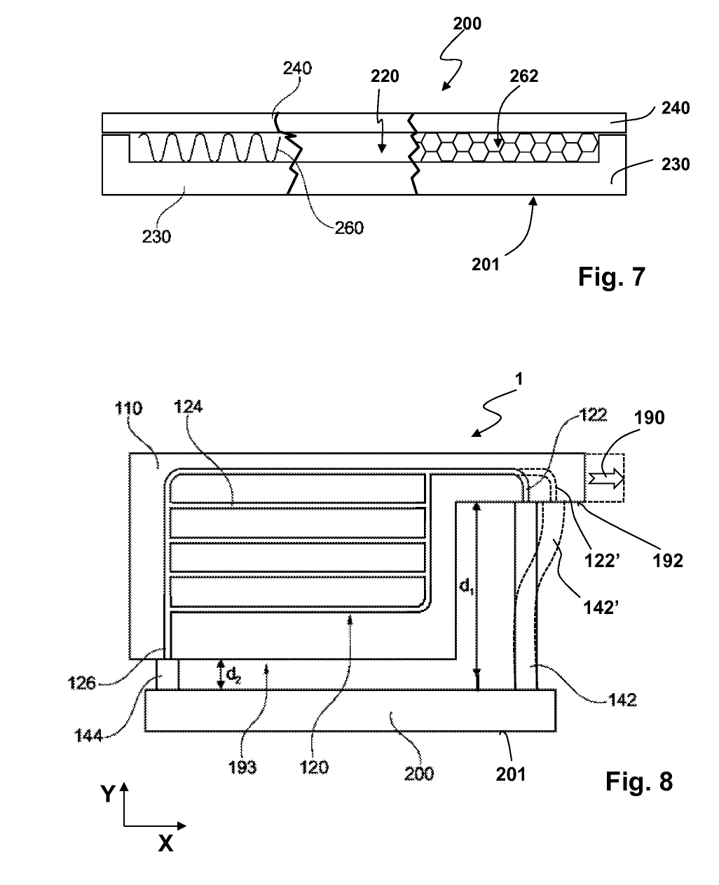

FIG. 7 shows a cross sectional view presented similar to FIG. 6 through an alternative base part. In difference to the base part referred to in FIGS. 4 to 6 the base part 230 according to this embodiment include a single longitudinal portion of the second channel 220 discharging at its ends into the first manifold 232 and the second manifold 236. A vapor promoting structure 260, 262 is provided in the longitudinal portion of the second channel 220 for improving the efficiency of the heat transfer from the evaporator body 200 to the working fluid by increasing the creation of nucleation sites for vaporizing the working fluid in an operating state of the evaporator body 200. The term “vapor promoting structure” should not be misunderstood as a known porous structure but as a blanket term for a structure for forming a plurality of sub-channels for enhancing the overall surface within the evaporator where the vaporization takes place, i.e. for enhancing the overall surface wetted by the working fluid in the evaporator.

FIG. 7 displays two exemplary embodiments of vapor promoting structure for achieving good vaporization results. The first embodiment shown in the left hand side fractional view of FIG. 7 has a vapor promoting structure 260 with a zigzag cross-section. In this embodiment, the vapor promoting structure 260 is formed by a corrugated sheet metal that is connected to the base part 230 and the cover plate 240 for example, by brazing in one shot together with the connection of the cover plate 240 to the base part 230. The vapor promoting structure 260 forms a plurality of sub-channels that extend parallel to one another in the direction X.

The vapor promoting structure is formed by a folded fin 260 that is located within the second channel 220 in order to increase the heat transfer from the base part to the working fluid and to improve the efficiency of the heat transfer to the working fluid such that vaporization of the working fluid is further promoted.

The fractional view on the right hand side of FIG. 7 features a vapor promoting structure 262 having a honey-comb cross-section. The vapor promoting structure 262 can be an extruded metal profile that is connected to the base part 230 and the cover plate 240 for example, by brazing in one shot together with the connection of the cover plate 240 to the base part 230. The vapor promoting structure 262 forms a plurality of sub-channels that extend parallel to one another in the direction X.

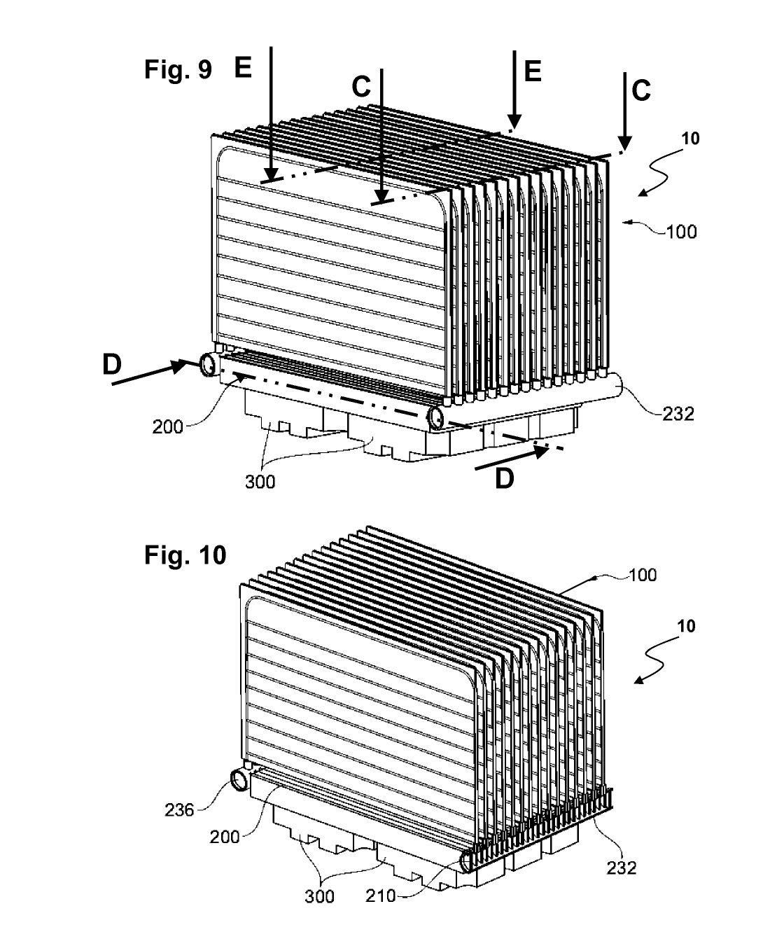

FIG. 8 shows a side view of an exemplary embodiment of a heat exchanger according to the disclosure. The movement of the working fluid in the operating state of the heat exchanger of this embodiment is driven by gravitation, too. The roll-bonded panel 110 is again connected to the evaporator body 200 via the first connection port 142 and the second connection port 144. In contrast to the embodiments described above where the first connection port 142 and the second connection port 144 were located at a straight first edge 190 of the roll-bonded panel 110, the first connection port 142 of this embodiment can be located on a first edge area 192 of the first edge 190 facing the evaporator body 200. The first edge area 192 is vertically displaced to the second connection port 144. The second connection port 144 is still located on a second edge area 193 in the area where the formerly common, straight first edge 190 of the aforementioned embodiments was located. In other words, the first edge area 192 and the second edge area 193 can be stepped against each other with respect to the evaporator or a surface of the cover plate oriented towards the roll-bonded panel. In other words, the first edge area 192 of the condenser body 100 runs at a first distance d1 to the evaporator surface facing the condenser. Similarly thereto runs the second edge area 193 of the condenser body 100 at a second distance d2 to the evaporator surface facing the condenser wherein the first distance d1 is larger than the second distance d2. Both the first distance d1 and the second distance d2 extend in the vertical distance (direction of Y). When connecting the pre-manufactured condenser body 100 to the pre-manufactured evaporator body 200 the ability of the first connection port 142 to be deformed and thus allowing a lateral deflection proofs particularly useful for heat exchangers whose roll-bonded panels can be subject to comparatively large dimensional tolerances of up to several millimeters already at an intended distance between the first connection port 142 and the second connection port 144 of about 400 mm, for example. Those tolerances occur due to the intrinsic manufacture tolerances of the roll-bond panels due to the manufacturing process involving a rolling operation. In contrast thereto, the third connection opening 242 and the fourth connection opening 244 dedicated to the roll-bonded panel 110 is cast or machined into the evaporator body 200 with comparatively small tolerances. Because of its rather high stiffness, the evaporator body 200 cannot compensate for large manufacturing tolerances. The comparatively flexible first connection port 142 allows for connecting the free end of the first connection port 142 facing the third connection opening 242 dedicated for receiving the first connection port 142 even if there is a dimensional mismatch in the X-direction between the intended beginning of the first connection port 142 adjacent to the first portion 122 of the first channel 120 and the actual beginning of the first connection port 142 adjacent to the misaligned first portion 122′ of the first channel 120 or a form/shape mismatch.

A further advantage of this embodiment resides in that the flexibility of the first connection port 142 allows a substantial change in length of the roll-bonded panel 110 due to differing thermal expansion between the beginning of the first connection port 142 and the second connection port, delimiting the first channel 120 longitudinally. FIG. 8 displays a heat exchanger whose first connection port 142′ is deflected at the proximate end to the roll-bonded panel 110.

The reference numeral 190 denotes a mismatch in location of that end of the roll-bonded panel 110 to which the beginning of the first connection port 142 is attached, regardless whether the mismatch is originating from manufacturing tolerances, differing thermal expansion or a mixture thereof.

FIG. 9 shows a perspective view of an exemplary embodiment of a power module according to the disclosure with a two-phase heat exchanger according to an exemplary embodiment according to the disclosure. In contrast to the embodiment of the power module shown in FIG. 3, the first manifold 232 and the second manifold 236 of this embodiment can be now formed by tubes or pipes that can be sealed at their end faces and can be arranged along the end faces of the base part 230 of the evaporator body. The third and fourth connection openings can be provided in the pipe forming the first manifold 232 and the second manifold 236, respectively. In contrast to the embodiments of the above-mentioned evaporators, this evaporator body does not need a cover plate for vertically delimiting the longitudinal portion of the second channel since said portion is provided and laterally delimited by a plurality of multi-port extruded (MPE) tubes 210 that will be explained with reference to FIG. 10 below.

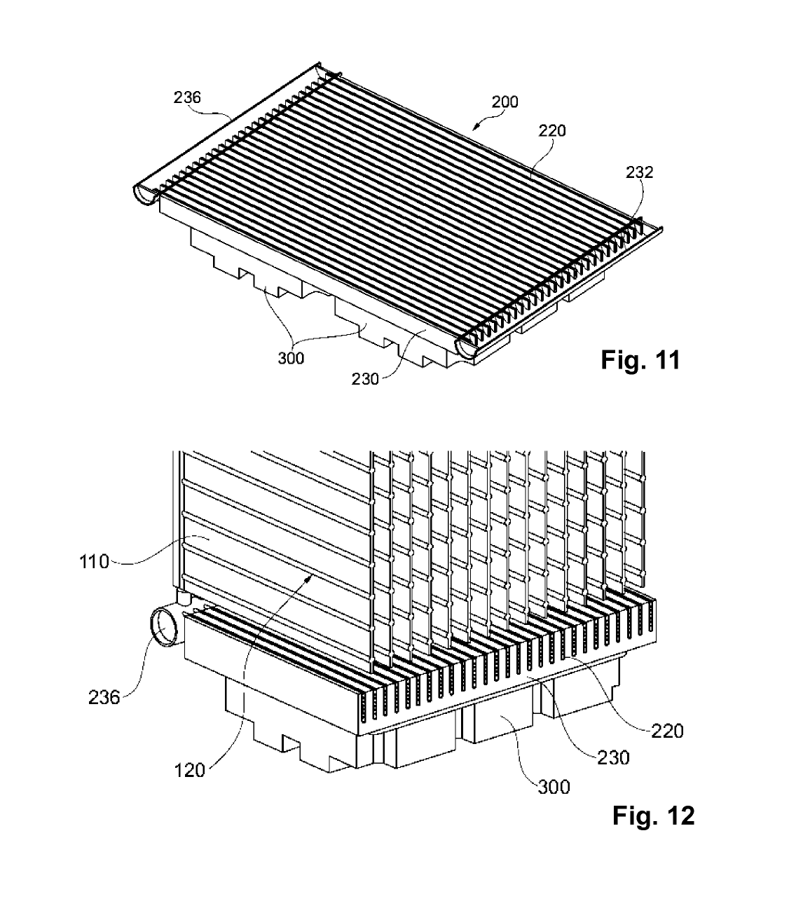

FIG. 10 shows a perspective view of the power module according to FIG. 9 including a sectional view through the condenser body and the evaporator body along section C-C in FIG. 9. A perspective view of the evaporator body according to this embodiment is shown in FIG. 13. Together with FIG. 11 it can be seen that the longitudinal portions of the second channels within the evaporator body 200 can be formed by means of MPE tubes 210 dedicated to each of these second channel portions. An MPE tube is an element includes a multitude of channels, for example, six channels. An MPE tube 210 is an inexpensive extruded metal profile, for example, made of aluminum or an alloy thereof. Each of the sub-channels of each multiport extruded tube 210 discharges into one of the second manifold 236 or the first manifold 232. The detailed set-up of this arrangement is visible in FIG. 12, showing a close-up of an exploded view of the power module according to FIG. 9 in a similar perspective as in FIG. 9 and including a sectional view through the evaporator body and the condenser body along section E-E in FIG. 9. The sectional area along E-E is not shown in hatched style as the latter might hamper the understandability and clarity of the cross-section.

The vaporization of the working fluid takes place within the sub-channels of the MPE tubes 210 that provide for a large interior surface wetted by the working fluid. For ensuring a good thermal transfer from the base part 230 to the working fluid, the base part 230 features a number of longitudinal slots matching the number of MPE tubes 210. The MPE tubes 210 can be bonded to the base part 230 by brazing, for example. Depending on the embodiment, the brazing of the MPE tubes 210 to the base part 230 as well as the first manifold 232 and the second manifold 236 to the base part 230 can be performed in one shot to form an evaporator body 200 as shown in FIG. 13. The number of MPE tubes 210 does not necessarily need to be the same as the number of roll-bonded panels 110 conferring good freedom of design properties to this heat exchanger.

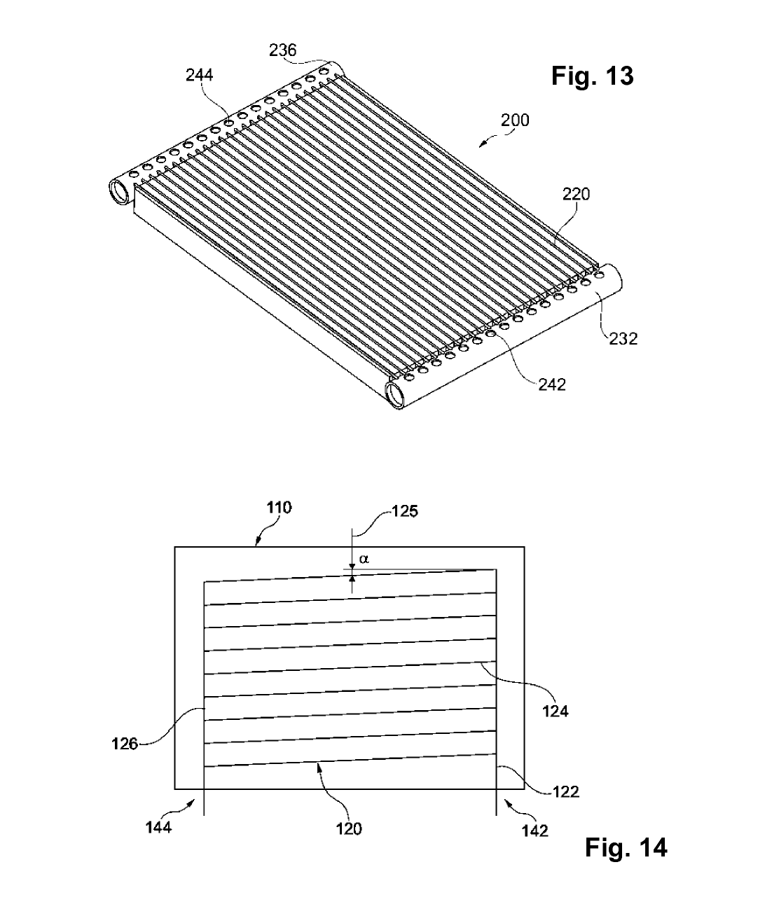

FIG. 14 shows a simplified side view of an exemplary roll-bonded condenser panel. The difference of the roll-bonded panel 110 of FIG. 14 to the roll-bonded panel 110 of the embodiment shown in FIG. 2 resides in that the third portions 124 can be inclined by an angle α which angle is denoted by reference numeral 125 with respect to said first portion 122 extending in the direction Y. The inclination is provided for conferring a predefined flowing direction to the working fluid in an operating state of the thermosyphon, if required.

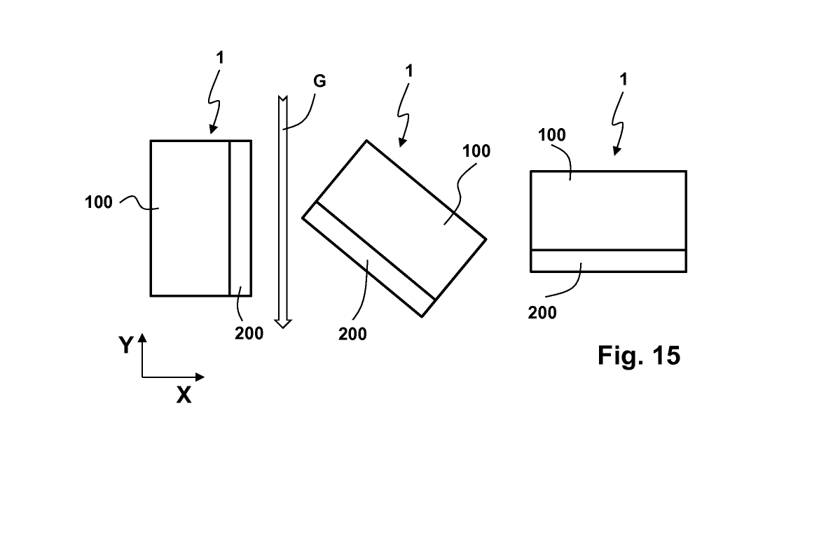

FIG. 15 shows possible orientations of the two-phase heat exchanger 1 according to the present application with respect to the direction (Y) of the gravitational force of the earth (arrow denoted by capital letter “G”) in an operating state of the power module. The evaporator 200 can be arranged horizontally and vertically as well as inclined with respect to a direction Y of the gravitation force G, wherein the roll-bonded panels can be oriented upwards, i.e. away from the gravitation force, in the inclined variant.

While the disclosure has been illustrated and described in detail in the drawings and the foregoing description, such illustration and description can be to be considered illustrative or exemplary and not restricted; the disclosure is not limited to the disclosed embodiments.

Other variations of the disclosed embodiments can be understood and effected by those skilled in the art and practicing the claimed disclosure, from a study of the drawings, the disclosure, and the appended claims.

Thus, it will be appreciated by those skilled in the art that the present invention can be embodied in other specific forms without departing from the spirit or essential characteristics thereof. The presently disclosed embodiments can be therefore considered in all respects to be illustrative and not restricted. The scope of the invention is indicated by the appended claims rather than the foregoing description and all changes that come within the meaning and range and equivalence thereof can be intended to be embraced therein.

What is claimed is:

1. A two-phase heat exchanger for cooling at least one of an electronic and an electric component, the heat exchanger comprising:
a condenser body including a plurality of roll-bonded panels having a first channel arranged between a first and a second sheet such that a first connection port delimits the first channel at one end and a second connection port delimits the first channel at another end, wherein the first sheet is connected to the second sheet by roll-bonding to form the roll-bonded panel; and
an evaporator body including a second channel, wherein the second channel is delimited at one end by a third connection opening for each roll-bonded panel and at another end by a fourth connection opening for each roll-bonded panel, wherein the evaporator body includes a thermal connection surface to which at least one of an electronic and an electric component is thermally connectable,
wherein the first connection port is connected to the third connection opening and wherein the second connection port is connected to the fourth connection opening such that the first channels and the second channel form a loop for guiding a working fluid that receives a thermal load producible by the at least one of an electronic and an electric component in an operating state of the heat exchanger at the evaporator body from the evaporator body to the condenser body for transferring the thermal load,
wherein the third connection openings can be arranged in a first end region of the evaporator body and wherein the fourth connection openings can be arranged in a second end region of the evaporator body, and
wherein the second end region is provided on an opposite end of the evaporator body with respect to the first end region.

2. The two-phase heat exchanger of claim 1,
wherein the third connection opening and the fourth connection opening are arranged on a common edge of the evaporator body.

3. The two-phase heat exchanger of claim 2,
wherein the common edge is arranged on a second surface of the evaporator body that is on a side opposite the connection surface on the evaporator body.

4. The two-phase heat exchanger according to claim 3,
wherein the first connection port and the second connection port are arranged at a first edge of the condenser body, the first edge facing the second surface of the evaporator body.

5. The two-phase heat exchanger according to claim 4,
wherein the first edge of the condenser body runs proximate to the second surface of the evaporator body.

6. The two-phase heat exchanger according to claim 2,
wherein the first connection port is longer than the second connection port, and the first connection port is flexible for allowing compensation for mismatches between the second connection port and the third connection opening.

7. The two-phase heat exchanger according to claim 1, comprising:
a plurality of sets of a third connection opening and a fourth connection opening for fluids connecting each of a plurality of condenser bodies to the evaporator body.

8. The two-phase heat exchanger according to claim 7, wherein at least two of the third connection openings and at least two of the fourth connection openings can be fluidly interconnected by a common second channel.

9. The two-phase heat exchanger according to claim 8, wherein the second channel comprises:
at least two sub-channels in between the third connection openings and the fourth connection openings.

10. The two-phase heat exchanger according to claim 1, comprising:
at least one vapor promoting structure arranged in the second channel.

11. The two-phase heat exchanger of claim 10,
wherein the vapor promoting structure has structure which, when seen in cross section in a flow direction of the working fluid in an operating state of the heat exchanger, forms a plurality of sub-channels of the second channel.

12. The two-phase heat exchanger according to claim 1, comprising:
a multi-port tube forming a portion of a length of the second channel or a sub-channel thereof.

13. The two-phase heat exchanger according to claim 1,
wherein the first channel is split into at least two sub-channels between the first connection port and the second connection port.

14. The two-phase heat exchanger according to claim 1,
wherein the condenser body and the evaporator body are connected to one another at one time by CAB brazing or vacuum brazing.

15. The two-phase heat exchanger according to claim 1, in combination with a power module and at least one of an electronic and an electric component that is thermally connected to the connection surface of the evaporator body.

16. The two-phase heat exchanger according to claim 1, in combination with a vehicle.
